(19) United States
(12) Patent Application Publication
(10) Pub. No.: US 2010/0009097 A1
(43) Pub. Date: Jan. 14, 2010

(54) Deposition Apparatus and Deposition Method Using the Same

(76) Inventors: Doug-Yong Sung, Suwon-si (KR); Moon-Hyeong Han, Seoul (KR); Andrey Ushakov, Suwon-si (KR); Hyu-Rim Park, Suwon-si (KR); Nam-Young Cho, Suwon-si (KR); Tae-Yong Kwon, Suwon-si (KR); Seoung-Hyun Seok, Suwon-si (KR); Dong-Woo Kang, Suwon-si (KR); Chang-Yun Lee, Suwon-si (KR); Dong-Ha Lee, Suwon-si (KR)

Correspondence Address: F. CHAU & ASSOCIATES, LLC, 130 WOODBURY ROAD, WOODBURY, NY, 11797, US

(21) Appl. No.: 12/389,921

(22) Filed: Feb. 20, 2009

(30) Foreign Application Priority Data
Jul. 14, 2008 (KR) 10-2008-0068174

(51) Int. Cl. C23C 16/513

(52) U.S. Cl. 427/569; 118/723 E

(57) ABSTRACT

A deposition apparatus includes a gas inflow tube, a plasma electrode, a substrate support functioning as an opposite electrode to the plasma electrode and mounting a substrate thereon, a plasma connector terminal connected to the plasma electrode, a first voltage application unit connected to the plasma connector terminal to apply a voltage thereto in a continuous mode, and a second voltage application unit connected to the plasma connector terminal to apply a voltage thereto in a pulse mode. The voltage applied by the first voltage application unit is an RF voltage of about 13.56 MHz, and the voltage applied by the second voltage application unit is a VHF voltage ranged from about 27 MHz to about 100 MHz.

### CROSS-REFERENCE TO RELATED APPLICATION

This application claims priority under 35 U.S.C. §119 from Korean Patent Application No. 10-2008-0068174 filed in the Korean Intellectual Property Office on Jul. 14, 2008, the entire contents of which are herein incorporated by reference in their entirety.

### BACKGROUND OF THE INVENTION

(a) Field of the Invention

The present disclosure is directed to a deposition apparatus, and more particularly, to a plasma deposition apparatus.

(b) Discussion of the Related Art

Generally, a silicon film for a solar cell is deposited by way of plasma enhanced chemical vapor deposition.

With plasma enhanced chemical vapor deposition, a low radio frequency (RF) power or a very high frequency (VHF) power can be used to generate the plasma.

However, when the plasma is generated using a low frequency power, ion density is too low to achieve the desired deposition rate, and so a high frequency power is used to increase the deposition rate. By contrast, when the plasma is generated using a high frequency power, the ion density is so high that a lower frequency power is sufficient to achieve the desired high deposition rate for making the thin film deposition within a shorter period of time, but with decreased uniformity of deposition.

### SUMMARY OF THE INVENTION

Embodiments of the present invention can provide a deposition apparatus having a heightened deposition rate with a high deposition uniformity, and a thin film deposition method using the same.

An exemplary embodiment of the present invention provides a deposition apparatus including a gas inflow tube, a plasma electrode, and a substrate support functioning as an opposite electrode to the plasma electrode and mounting a substrate thereon. A plasma connector terminal is connected to the plasma electrode. A first voltage application unit is connected to the plasma connector terminal to apply a first voltage thereto in a continuous mode. A second voltage application unit is connected to the plasma connector terminal to apply a second voltage thereto in a pulse mode.

The second voltage has a duty cycle of about 20% to 90%.

The second voltage has a pulse frequency of about 1 Hz to 100 Hz.

The first voltage and the second voltage may differ in frequency from each other.

The first voltage may be an RF voltage, while second voltage may be a VHF voltage.

The second voltage may be a VHF voltage ranged from about 27 MHz to about 100 MHz.

The first voltage may be an RF voltage of about 13.56 MHz.

An exemplary embodiment of the present invention provides a deposition method including the steps of flowing a process gas into a reactor with a substrate mounted therein, applying a first voltage to the reactor in a continuous mode, and applying a second voltage to the reactor in a pulse mode.

The reactor may have an internal pressure of about 250 mtorr or less.

The second voltage may be applied after the first voltage.

The first voltage may be applied substantially simultaneously with the second voltage.

The first voltage may be an RF voltage of about 13.56 MHz, while the second voltage may be a VHF voltage ranged from about 27 MHz to about 100 MHz.

The application of the second voltage may be made at a duty cycle of about 20% to about 90%.

The application of the second voltage may be made at a pulse frequency of about 1 Hz to about 100 Hz.

In an exemplary embodiment of the present invention, a pulse-mode high frequency power is supplied to a plasma electrode simultaneously with a low frequency power, and a substantially uniform thin film can be deposited with a high deposition rate.

### BRIEF DESCRIPTION OF THE DRAWINGS

FIG. 1 is a schematic cross-sectional view of a deposition apparatus according to an exemplary embodiment of the present invention.

FIG. 2A and FIG. 2B are power output waveform diagrams of a power supply according to an exemplary embodiment of the present invention.

FIG. 3 is a flowchart illustrating a thin film deposition method according to an exemplary embodiment of the present invention.

FIG. 4 is a flowchart illustrating a thin film deposition method according to another exemplary embodiment of the present invention.

FIG. 5A and FIG. 5B are photographs of a surface of a deposited thin film.

FIG. 6A and FIG. 6B are graphs illustrating the Raman spectra of a deposited thin film.

FIG. 7A and FIG. 7B are scanning electron microscopy (SEM) photographs of a deposited thin film.

### DETAILED DESCRIPTION OF EXEMPLARY EMBODIMENTS

Embodiments of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present.

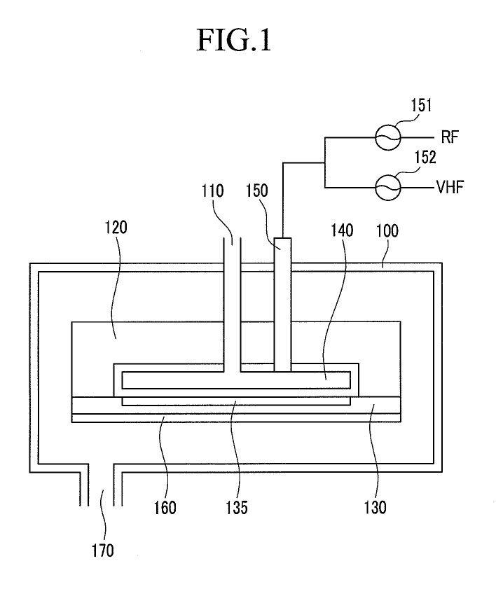

A deposition apparatus according to an exemplary embodiment of the present invention will be first described with reference to FIG. 1. FIG. 1 is a schematic cross-sectional view of a deposition apparatus according to an exemplary embodiment of the present invention.

Referring to FIG. 1, a deposition apparatus according to an exemplary embodiment of the present invention includes an outer wall 100, a gas inflow tube 110, a reactor wall 120, a substrate support 130, a substrate 135 mounted on the substrate support 130, a plasma electrode 140, a plasma connector terminal 150, a first voltage application unit 151 and a second voltage application unit 152, a heater 160, and a gas outflow tube 170.

The outer wall 100 of the deposition apparatus prevents the heat generated in the reactor from being conducted to the outside and lost.

The substrate 135, being a target of the deposition, is mounted on the substrate support 130, and the heater 160 is disposed under the substrate support 130. The heater 160 elevates the temperature of the substrate 135 up to the degree required for the processing.

The reactor wall 120 and the substrate support 130 are tightly adhered to each other during the deposition process to define the reactor.

The gas inflow tube 110 is inserted into the plasma electrode 140, and the plasma connector terminal 150 is connected to the plasma electrode 140. Although one gas inflow tube 110 is illustrated with the present exemplary embodiment, a plurality of gas inflow tubes may be provided to inflow different process gases therethrough, respectively.

The substrate support 130 and the substrate 135 each function as an opposite electrode to the plasma electrode 140 during the deposition process. Although not shown in the drawings, power may be supplied to the substrate support 130 through an additional plasma connector terminal (not shown).

With a deposition apparatus according to an exemplary embodiment of the present invention, the first and the second voltage application units 151 and 152 are connected to the plasma connector terminal 150. A radio frequency (RF) voltage is applied to the plasma connector terminal 150 by way of the first voltage application unit 151, while a very high frequency (VHF) voltage is applied thereto by way of the second voltage application unit 152.

When a process gas flows in through the gas inflow tube 110, and the voltages from the first and the second voltage application units 151 and 152 are applied to the plasma electrode 140 via the plasma connector terminal 150, the process gas flowing into the reactor is converted into plasma due to the voltage difference between the plasma electrode 140 and the substrate support 130, and is deposited onto the substrate 135.

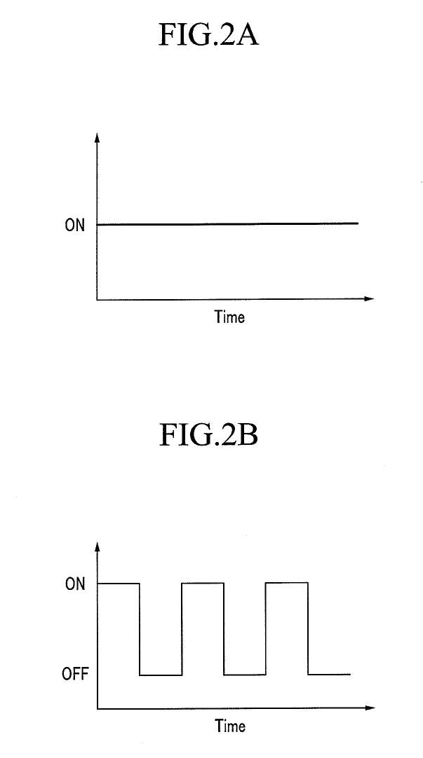

FIG. 2A and FIG. 2B are voltage output waveform diagrams of a power supply according to an exemplary embodiment of the present invention. FIG. 2A is an output waveform diagram of a radio frequency (RF) voltage applied by the first voltage application unit 151, and FIG. 2B is an output waveform diagram of a very high frequency (VHF) voltage applied by the second voltage application unit 152.

As shown in FIG. 2A, the first voltage application unit 151 according to an exemplary embodiment of the present invention applies a radio frequency (RF) voltage continuously during the voltage on period. That is, the first voltage unit 151 applies the RF voltage in a continuous mode. In this case, the frequency of the RF voltage is about 13.56 MHz.

As shown in FIG. 2B, the second voltage application unit 152 according to an exemplary embodiment of the present invention applies a very high frequency (VHF) voltage in a pulse mode where ON and OFF are repeated at a predetermined cycle. That is, the second voltage application unit 152 applies the VHF voltage intermittently (off and on).

In this case, the frequency of the VHF voltage ranges from about 27 MHz to about 100 MHz. With the application of the VHF voltage, the duty cycle being the ON/OFF ratio may be established to be about 20% to about 90%, and the pulse frequency to be about 1 Hz to about 100 Hz.

Furthermore, the application ratio of the RF voltage to the VHF voltage may be controlled to be about 5:95 to about 95:5 depending upon the processing conditions.

In this way, as a deposition apparatus according to an exemplary embodiment of the present invention has an RF voltage application unit and a VHF voltage application unit, the continuous RF voltage is applied simultaneously with the pulse-mode intermittent VHF voltage, securing the desired deposition uniformity based on the RF voltage and increasing the deposition rate based on the VHF voltage while reducing the power consumption. Furthermore, the VHF voltage is intermittently (off and on) applied in a pulse mode, reducing non-uniform deposition due to the application of the VHF voltage.

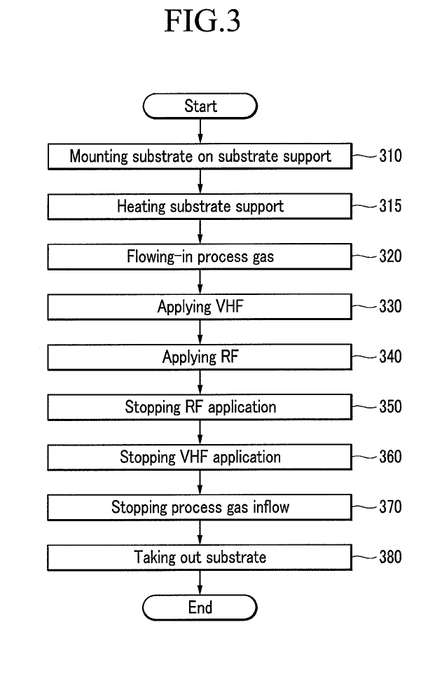

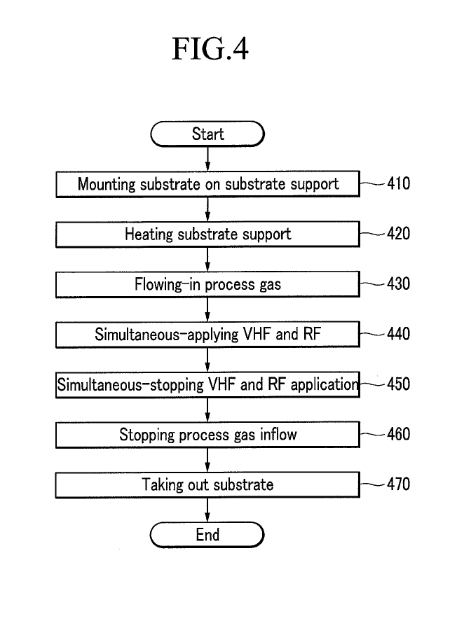

FIG. 3 is a flowchart illustrating a thin film deposition method according to an exemplary embodiment of the present invention, and FIG. 4 is a flowchart illustrating a thin film deposition method according to another embodiment of the present invention.

Referring to FIG. 3, in a thin film deposition method according to an exemplary embodiment of the present invention, a substrate 135 to be overlaid with a thin film is mounted on a substrate support 130 at a first step 310, and the substrate support 130 is heated using a heater 160 at a second step 315 to increase the temperature of the substrate 135 to a degree required for processing. A reactor for the deposition of a thin film may have an internal pressure of about 250 mtorr or less.

Thereafter, a process gas flows into the reactor through a gas inflow tube 110 at a third step 320. For example, silane (SiH₄) gas and hydrogen (H₂) gas may be fed thereto as a process gas for forming a silicon film.

A VHF voltage is intermittently applied to the reactor in a pulse mode to generate plasma from the process gas at a fourth step 330, and then, an RF voltage is continuously applied thereto at a fifth step 340.

The frequency of the RF voltage is established to be about 13.56 MHz, and the frequency of the VHF voltage to be about 27 MHz to about 100 MHz. Furthermore, with the application of the VHF voltage, the duty cycle, the ratio of ON to OFF, may be about 20% to about 90%, and the pulse frequency may be about 1 Hz to about 100 kHz. Furthermore, the ratio of the VHF voltage application time to the RF voltage application time may be controlled to be in the range of about 5:95 to about 95:5.

Thereafter, when a thin film with the desired thickness is deposited, the RF voltage is turned OFF at a sixth step 350, and the VHF voltage is turned OFF at a seventh step 360. The inflow of the process gas is then stopped at an eighth step 370, and the substrate 135 is taken out of the reactor at a ninth step 380, completing the thin film deposition process.

A thin film deposition method according to another exemplary embodiment of the present invention will be now described with reference to FIG. 4.

A substrate 135 is mounted onto a substrate support 130 at a first step 410, and the substrate support 130 is heated using a heater 160 at a second step 420. A process gas flows into the reactor through a gas inflow tube 110 at a third step 430, and an RF voltage and a VHF voltage are applied thereto at a fourth step 440. After a thin film is deposited with the desired thickness, the RF voltage and the VHF voltage are turned OFF at a fifth step 450, and the inflow of the process gas is stopped at a sixth step 460. The substrate 135 with the deposited film is removed from the reactor at a seventh step 470.

A deposition method according to the exemplary embodiment of FIG. 4 is differentiated from that illustrated in FIG. 3 in that the RF voltage and the VHF voltage are applied simultaneously. In this case, the frequency of the RF voltage may be about 13.56 MHz and the frequency of the VHF voltage may be about 27 MHz to 100 MHz. Furthermore, the VHF voltage is intermittently applied in a pulse mode. With the application of the VHF voltage, the duty cycle may be about 20% to about 90%, and the pulse frequency may be about 1 Hz to about 100 kHz.

In a deposition method according to the present exemplary embodiment where the application or stoppage of the RF voltage and the VHF voltage is performed simultaneously, the ratio of application time of the VHF voltage to the RF voltage is about 1:1.

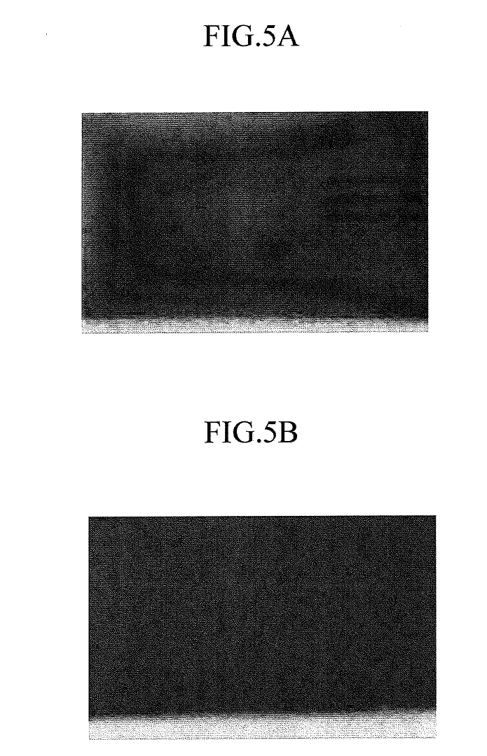

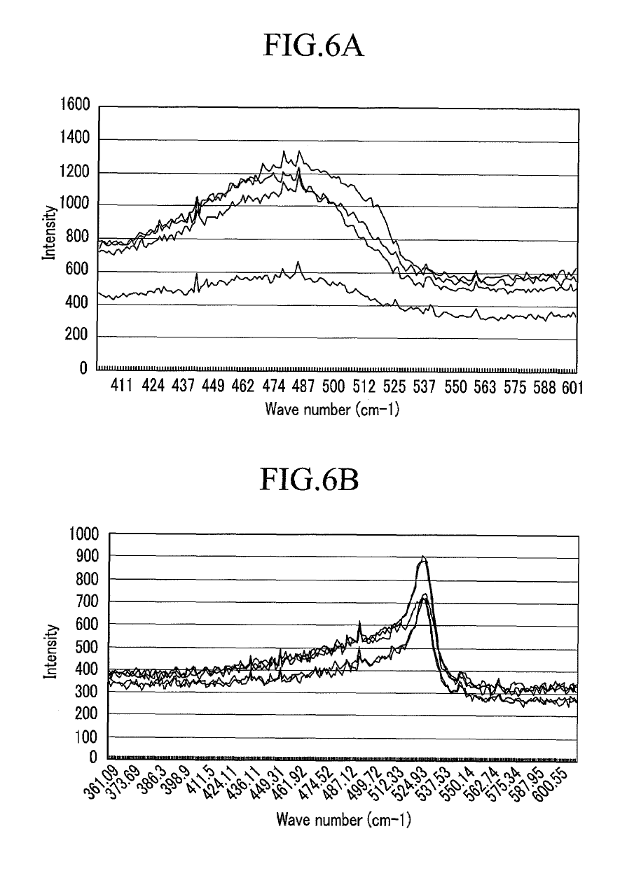

FIG. 5A and FIG. 5B are photographs of a surface of a thin film deposited using a deposition apparatus and a deposition method according to an embodiment of the invention, and FIG. 6A and FIG. 6B are graphs illustrating the Raman spectra of a thin film deposited using a deposition apparatus and a deposition method according to an embodiment of the invention.

FIG. 5A and FIG. 6A illustrate a case in which silane (SiH₄) flowed into a glass substrate with a thickness of about 0.3 mm under a reactor pressure of about 130 mtorr with a flux of about 5 sccm, and hydrogen (H₂) gas flowed-in thereto with a flux of about 200 sccm, and in which a VHF voltage of about 60 MHz was applied thereto using a power supply of about 1000 W to deposit a silicon film on the substrate. By contrast, as illustrated in FIG. 5B and FIG. 6B, in an exemplary embodiment of the present invention, a VHF voltage of about 60 MHz was applied to a glass substrate using a power supply of about 1000 W in a pulse mode, and simultaneously, an RF voltage of about 13.56 MHz was applied thereto using a power supply of about 200 W to deposit a silicon film on the substrate. The deposited silicon films were photographed on the surfaces thereof, and compared to each other. The Raman spectra of the silicon films were measured at five points on the surfaces thereof, and the measurement results were graphed.

The silicon film was deposited using plasma enhanced chemical vapor deposition. In the latter case according to an exemplary embodiment of the present invention, the pulse frequency of the VHF voltage was about 10 kHz, and the duty cycle was about 50%.

In the case illustrated in FIG. 5A in which a silicon film was deposited using only a VHF voltage according to a prior art, the surface of the silicon film has a non-uniform wave-pattern. By contrast, in the case according to an exemplary embodiment of the present invention illustrated in FIG. 5B in which a silicon film was deposited using a VHF voltage intermittently applied in a pulse mode simultaneoulsy with a continuously-applied RF voltage, the surface of the silicon film was substantially uniform with no height variations.

FIG. 6A illustrates the Raman spectra of a silicon film deposited using only a VHF voltage according to a prior art, and FIG. 6B illustrates the Raman spectra of a silicon film deposited using a VHF voltage intermittently applied in a pulse mode simultaneoulsy with a continuously-applied RF voltage according to an exemplary embodiment of the present invention. As shown in FIG. 6A and FIG. 6B, the Raman spectra of the former was greater in magnitude than the Raman spectra of the latter.

In particular, the crystal volume fraction was computed using values of Raman spectra in the two cases. For the case in which the silicon film was deposited using only a VHF voltage according to a prior art, the crystal volume fraction was about 40%. By contrast, for the case in which the silicon film was deposited using a pulse-mode VHF voltage simultaneously with a continuous RF voltage according to an exemplary embodiment of the present invention, the crystal volume fraction was about 68%. Accordingly, when a silicon film was deposited using a pulse-mode VHF voltage simultaneously with a continuous RF voltage according to an exemplary embodiment of the present invention, the crystal volume fraction thereof was high, and hence, the deposition was substantially uniform with minute-sized particles.

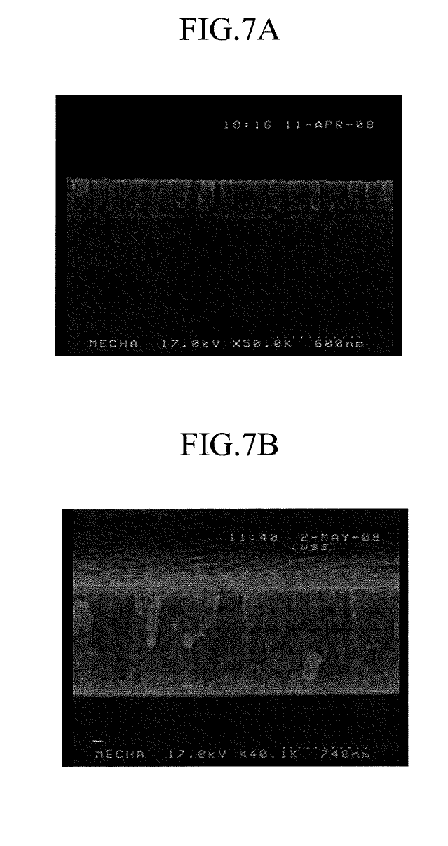

Film characteristics of a thin film deposited using a deposition apparatus and a deposition method according to another embodiment of the present invention will be described with reference to FIG. 7A and FIG. 7B. FIG. 7A and FIG. 7B are SEM photographs of a deposited thin film.

The deposition conditions of a deposition method according to an exemplary embodiment of the present invention were varied to deposit silicon films. FIG. 7A illustrates a case in which silane (SiH₄) flowed into a reactor under a reactor pressure of about 130 mtorr with a flux of about 5 sccm, and hydrogen (H₂) gas flowed-in thereto with a flux of about 200 sccm, and a VHF voltage of about 60 MHz was intermittently applied thereto in a pulse mode using a power supply of about 1000 W, and simultaneously, an RF voltage of about 13.56 MHz was continuously applied thereto using a power supply of about 200 W to deposit a silicon film. FIG. 7B illustrates a case in which silane (SiH₄) flowed into a reactor under a reactor pressure of about 250 mtorr with a flux of about 60 sccm, and hydrogen (H₂) gas flowed-in thereto with a flux of about 750 sccm. A VHF voltage of about 60 MHz was intermittently applied thereto in a pulse mode using a power supply of about 3000 W, and simultaneously, an RF voltage of about 13.56 MHz was continuously applied thereto using a power supply of about 150 W to deposit a silicon film. The resulting silicon films were photographed by a scanning electron microscope.

As shown in FIG. 7A and FIG. 7B, the resulting silicon films had uniformly-formed surfaces with minute-sizes particles. Furthermore, compared with the silicon film shown in FIG. 7B, the silicon film shown in FIG. 7A has a more uniformly-formed film surface with smaller sized particles. That is, compared with the silicon film shown in FIG. 7A, with the silicon film shown in FIG. 7B, as the power of the VHF voltage increased from about 1000 W to about 3000 W while that of the RF voltage decreased from about 200 W to about 150 W, the film uniformity reduced somewhat, but the film thickness increased, increasing the deposition yield.

As described above, with a thin film deposition method according to an exemplary embodiment of the present invention, a thin film with desired film characteristics can be deposited by controlling the application time and power magnitude of a continuous-mode RF voltage and an intermittent pulse-mode VHF voltage.

While embodiments of this invention have been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus comprising:
a gas inflow tube;
a plasma electrode;
a substrate support functioning as an opposite electrode to the plasma electrode and mounting a substrate thereon;
a plasma connector terminal connected to the plasma electrode;
a first voltage application unit connected to the plasma connector terminal to apply a first voltage thereto in a continuous mode; and
a second voltage application unit connected to the plasma connector terminal to apply a second voltage thereto in a pulse mode.

2. The deposition apparatus of claim 1, wherein the second voltage has a duty cycle of about 20% to about 90%.

3. The deposition apparatus of claim 1, wherein the second voltage has a pulse frequency of about 1 Hz to 100 Hz.

4. The deposition apparatus of claim 1, wherein the first voltage and the second voltage differ in frequency from each other.

5. The deposition apparatus of claim 4, wherein the first voltage is a radio frequency (RF) voltage.

6. The deposition apparatus of claim 5, wherein the second voltage is a very high frequency (VHF) voltage.

7. The deposition apparatus of claim 6, wherein the second voltage ranges from 27 MHz to about 100 MHz.

8. The deposition apparatus of claim 6, wherein the voltage applied by the first voltage application unit is an RF voltage of 13.56 MHz, and the voltage applied by the second voltage application unit is a VHF voltage.

9. The deposition apparatus of claim 8, wherein the voltage applied by the second voltage application unit is a VHF voltage ranged from 27 MHz to 100 MHz.

10. A deposition method comprising the steps of:
flowing a process gas into a reactor with a substrate mounted therein;
applying a first voltage to the reactor in a continuous mode; and
applying a second voltage to the reactor in a pulse mode,
wherein the first voltage is applied substantially simultaneously with the second voltage.

11. The deposition method of claim 10, wherein the reactor has an internal pressure of about 250 mtorr or less.

12. The deposition method of claim 11, wherein the first voltage is an RF voltage, and the second voltage is a VHF voltage.

13. The deposition method of claim 12, wherein the first voltage is an RF voltage of about 13.56 MHz, and the second voltage is a VHF voltage ranged from about 27 MHz to about 100 MHz.

14. The deposition method of claim 10, wherein the application of the second voltage is made at a duty cycle of about 20% to about 90%.

15. The deposition method of claim 10, wherein the application of the second voltage is made at a pulse frequency of about 1 Hz to about 100 Hz.

16. A deposition method comprising the steps of:
flowing a process gas into a reactor with a substrate mounted therein;
applying a first voltage to the reactor in a continuous mode; and
applying a second voltage to the reactor in a pulse mode, wherein the second voltage is applied after the first voltage.

17. The deposition method of claim 16, wherein the first voltage is an RF voltage, and the second voltage is a VHF voltage.

18. The deposition method of claim 17, wherein the first voltage is an RF voltage of about 13.56 MHz, and the second voltage is a VHF voltage ranged from about 27 MHz to about 100 MHz.

19. The deposition method of claim 18, wherein the application of the second voltage is made at a duty cycle of about 20% to about 90%.

20. The deposition method of claim 18, wherein the application of the second voltage is made at a pulse frequency of about 1 Hz to about 100 Hz.
